(19) United States
(12) Patent Application Publication
(10) Pub. No.: US 2002/0123004 A1
(43) Pub. Date: Sep. 5, 2002

(54) Lithographic printing plate with improved hydrophilicity and method of manufacture and method of printing

(76) Inventors: Howard A. Fromson, Stonington, CT (US); William J. Rozell, Vernon, CT (US)

Correspondence Address: Alix, Yale & Ristas, LLP, 750 Main Street, Hartford, CT, 06103-2721, US

(21) Appl. No.: 10/013,867

(22) Filed: Oct. 30, 2001

Related U.S. Application Data
(63) Continuation-in-part of application No. 09/630,223, filed on Aug. 1, 2000, now abandoned.

(51) Int. Cl. G03F 7/11; G03F 7/26; B41N 1/08

(52) U.S. Cl. 430/278.1; 430/302; 101/451

(57) ABSTRACT

An imageable lithographic printing plate has a substrate with an aluminum base and a quantity of alumina particles embedded and retained in the aluminum base. The quantity of embedded and retained particles is relatively high thereby increasing the hydrophilicity of the base. The regions of the aluminum base between the embedded particles may optionally be anodized. The substrate has a coating which is imageable by absorbing the selective imaging radiation.

This application is a continuation-in-part of U.S. Pat. application Ser. No. 09/630,223 filed Aug. 1, 2000.

The invention relates to lithographic printing plates and in particular to an improved printing plate with enhanced hydrophilicity and imageability and to the method of manufacture of the plate and the method of using the plate in printing.

### BACKGROUND OF THE INVENTION

Conventional lithographic printing plates, such as those typically used by both newspaper and commercial printers, are usually made of a grained, anodized aluminum substrate which has been coated with a radiation sensitive coating. Graining of aluminum is accomplished in a variety of ways, including rotary brush graining, chemical graining and electrochemical graining. It is possible to use more than one of these techniques in the production of lithographic substrates. One of the benefits of a grained surface is that it provides better adhesion of the radiation sensitive coating to the surface. Another benefit is that the surface carries the aqueous fountain solution in the background areas of the plate more efficiently than an ungrained surface. The grained, anodized aluminum is generally post treated to enhance the hydrophilicity of the substrate prior to the application of the radiation sensitive coating. Solutions which are well known in the art for post treatment include, for example, sodium silicate and polyvinylphosphonic acid solutions. These post treatments significantly improve the initial hydrophilicity but after some number of printing impressions, the post treatment materials are eroded from the surface, resulting in a loss of hydrophilicity.

Brush graining with an abrasive slurry to roughen an aluminum sheet for use as a printing plate substrate is known in the art. Residual abrasive in a brush-grained surface has always been regarded as a contaminant from both a visual and functional perspective. The objective of normal brush graining is to texture the surface, not to embed particles. In practice, most of the abrasive which is embedded during the graining operation is removed by subsequent treatment including cleaning and anodizing. Cleaning typically involves an etch of some type, most typically an alkaline etch. The objective of the etch is to remove as much of the embedded abrasive as practical for maximum exposure of the roughened aluminum surface and to improve the cosmetic appearance of the final substrate product. In the case of an alkaline etch, it is customary to follow with a desmut process to further remove particles and improve the cosmetics of the aluminum sheet. Nitric acid is a typical desmutting agent. The subsequent process of anodizing to electrolytically generate aluminum oxide on the surface of the aluminum sheet may further remove particles depending on the anodizing conditions.

U.S. Pat. No. 4,731,317 to Fromson et al discloses a printing plate based on a substrate which is brush grained using a slurry comprising alumina followed by successive treatments in dilute sodium hydroxide and nitric acid to remove embedded particles and desmut the plate. The plate is subsequently anodized to achieve an oxide coating weight of 1.5 milligrams per square inch. The substrate may also be silicated after anodizing to improve hydrophilicity in accordance with U.S. Pat. No. 3,181,461. An imageable coating is then applied to the anodized plate.

U.S. Pat. No. 6,145,565, also to Fromson et al, discloses a lithographic printing plate which has a substrate which is also brush grained. For this specific lithographic printing plate, the graining particles which are embedded into the surface of the substrate by the graining process are retained in the final product. Most of the particles are covered over by a skin of the metal as a result of the extensive roughening. The reason why the graining particles are retained is that the plate uses a unique imaging process. The imageable coating applied to the substrate is transparent to the imaging infrared laser radiation. The imaging radiation passes through the coating and is absorbed by the surface of the substrate containing the retained particles thus heating the substrate surface. This surface heat is then transferred to the coating causing imaging by ablation.

### SUMMARY OF THE INVENTION

An object of the present invention is to provide an improved imageable lithographic printing plate with enhanced hydrophilicity and imageability. Objects are also to provide a method of manufacturing such a plate and using it in a printing operation. The plate has a coating which absorbs the imaging radiation and produces an image by any of the known imaging processes including either insolubilizing or solubilizing the coating in the radiation exposed areas. Also included are coatings which ablate by the absorption of the imaging radiation within the coating. This is hereinafter referred to as internal ablation. In particular, the invention involves the formation of a composite lithographic printing plate substrate having an aluminum base and calcined alpha alumina particles forged or embedded into and firmly fixed to the base and protruding therefrom. Preferably, an anodic aluminum oxide is formed on the base between the protruding particles. In accordance with the present invention, the quantity of particles embedded into and retained in the surface is sufficient to increase hydrophilicity. Therefore, plate treatments which would tend to remove particles as practiced in the prior art are excluded. The hydrophilicity is such that the plate does not require post treatment with a silicate or other materials to increase hydrophilicity. The fountain solution requirement in the non-image areas of the printing plate is significantly reduced which allows for a reduction in ink consumption and improvement in print quality. The surface retains its improved hydrophilicity during the printing operation on the press. A lithographic printing plate according to the invention is defined as a separate plate which has been prepared according to the invention and is attached to the exterior surface of a printing plate cylinder or defined as the actual exterior surface of the printing plate cylinder which has been prepared according to the invention.

### BRIEF DESCRIPTION OF THE DRAWINGS

FIG. 1 is a cross-section of a printing plate according to the invention.

FIG. 2 is a plot of the area occupied by the particles on the surface of a section of a plate according to the invention at 1 500× magnification.

FIG. 3 is a plot similar to FIG. 2 showing the area occupied by the particles remaining on the surface of a conventional prior art post treated plate.

FIG. 4 is a plot of the area of imprints remaining in the surface of the conventional plate of FIG. 3 by the particles which have been removed by the post treatment.

FIG. 5 is a magnified image of a droplet of water solution on the substrate surface of a printing plate according to the present invention.

FIG. 6 is an image similar to FIG. 5 but for the substrate surface of a printing plate of the prior art.

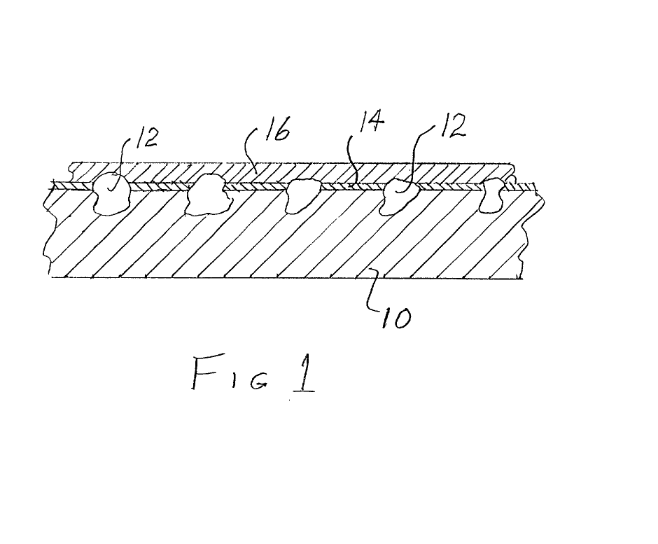

### PREFERRED EMBODIMENT OF THE INVENTION

The present invention relates to a lithographic printing plate with enhanced hydrophilicity. More specifically, the invention relates to a lithographic printing plate substrate comprising an aluminum base with a quantity of calcined alpha alumina particles embedded in and firmly fixed to the base and protruding therefrom. The substrate is preferably anodized between the embedded particles and the substrate has a coating which is imageable by absorption of the imaging radiation.

In a preferred embodiment of the invention, the substrate is prepared on a continuous coil processing line. The aluminum web is first subjected to a cleaning or degreasing process to remove milling oil residue from the surface. These processes are well known in the art of preparing aluminum surfaces for subsequent anodization. The aluminum web is rinsed in water after the cleaning step. It is next subjected to a rotary-brush graining process with axially rotating brushes that tangentially contact the web with a slurry comprised of calcined alpha alumina particles less than 10 microns and preferably less than 5 microns in size. The present invention embeds the quantity of particles required to produce the increased hydrophilicity.

As previously discussed, the conventional prior art lithographic printing plate substrates which have been rotary brush grained with calcined alumina are both etched and desmutted and aggressively anodized such that a large percentage of the graining particles are removed from the surface. It has been found that as little as 1% of the surface area of the plate is occupied by retained alumina particles in normally processed plates. Such normal plate substrate surfaces are usually post treated with a silicate to increase the hydrophilicity to an acceptable level. With the present invention, it has been discovered that the hydrophilicity of the substrate is significantly increased by retaining the embedded particles in the substrate when the quantity of alumina particles occupy 2% or more and preferably about 5% of the surface area of the plate. Increasing the particle population level above 5% is not detrimental from a functional standpoint. However, the upper limit is dictated by the cost/benefit ratio.

While rotary-brush graining has been shown to be an efficient method for producing these surfaces, other equivalent methods such as high pressure rolling, grit blasting, ball graining, or the like, which give rise to embedded particulate material may also be used. Graining techniques that do not embed particles such as chemical or electrochemical graining, known to produce suitable lithographic surfaces, will not produce a surface in accordance with the invention. When the term rotary-brush graining is referred to, it is to be understood that the other alternate or equivalent techniques can be used.

Subsequent to the brush-graining process, treatment with harsh chemicals may cause the surface to lose its properties. For example, etching with sodium hydroxide, as disclosed in U.S. Pat. No. 4,731,317 and as universally used in the prior art brush-graining processes, alters the surface by removing almost all of the particles that are necessary in the present invention to provide the increased hydrophilicity. Such harsh treatments that remove particles are excluded in the present invention.

After graining, the aluminum web is rinsed in water and preferably anodized by methods which are well understood in the art. The anodizing is carried out under relatively mild conditions to prevent the removal of particles from the surface. The electrolyte can be, for example, sulfuric acid or phosphoric acid. Sulfuric acid is preferred since it allows for oxide formation at lower dissolution rates. The anodizing is further preferentially carried out at relatively lower temperatures to further minimize the redissolution of the anodic oxide coating with the added benefit of producing a harder oxide layer than anodizing processes at higher electrolyte temperatures. U.S. Pat. Re 29,754 to Fromson discloses a preferred method for anodizing.

The next step in the formation of the completed lithographic printing plate is the application of the imageable coating. This coating can be any coating that is imaged by absorption of the imaging radiation. The coating may be positive working, where the imaging solubilizes the coating in the written areas, or negative working, where the imaging insolubilizes the coating in the written areas. Imaging can be accomplished through a film in a conventional exposure frame, or via direct writing by a modulated laser. The coating may be selected to be sensitive to ultraviolet, visible or infrared radiation. Coatings sensitive in these spectral regions are known to those skilled in the art. Alternatively, the coating may be internally ablated by absorbing the imaging radiation in the coating itself at an intensity that will cause ablation. The term “internally ablated” is intended to contrast with ablation achieved with absorption of the radiation by the substrate itself which serves to ablate the coating. Other ablation processes employing radiation absorptive subcoatings under the ablatable coating may be utilized to achieve ablation. Coatings of these types are also known to those skilled in the art. The aforementioned examples are merely intended to illustrate the wide range of coating systems and imaging methods for which the substrate of the present invention is suitable and are in no way intended to be limiting. The only limitation is that the coating contains an absorber for the imaging radiation.

A printing plate according to the invention is illustrated in cross section in the drawing which shows an aluminum base 10, embedded calcined alpha alumina particles 12, the preferred anodic oxide 14 and the radiation absorbing imageable coating 16. As compared to a lithographic printing plate with an anodized substrate without embedded particles or without any significant embedded particles, the plate of the present invention has substantially increased hydrophilicity. The following examples illustrate this benefit of the invention. Each of the examples was initially prepared by rotary brush graining using fourteen inch diameter brushes with nylon filaments and a abrasive slurry containing 30% calcined alpha alumina.

### EXAMPLE 1

The aluminum substrate was rotary brush grained as indicated above to the point that the surface was loaded with approximately 1.95×10¹⁰ particles per square meter as measured by an environmental scanning electron microscope. The plate was then anodized in a conventional manner.

### EXAMPLE 2

The aluminum substrate was rotary brush grained as in Example 1 to produce the same particle loading. The grained plate was then etched with sodium hydroxide and desmutted with nitric acid as is the procedure in the prior art. The plate was then anodized as in Example 1.

### EXAMPLE 3

This plate was produced as in Example 2 and then treated with a 3% aqueous solution of sodium silicate at 190° F. to increase the hydrophilicity. This is typical of the substrates used in the prior art.

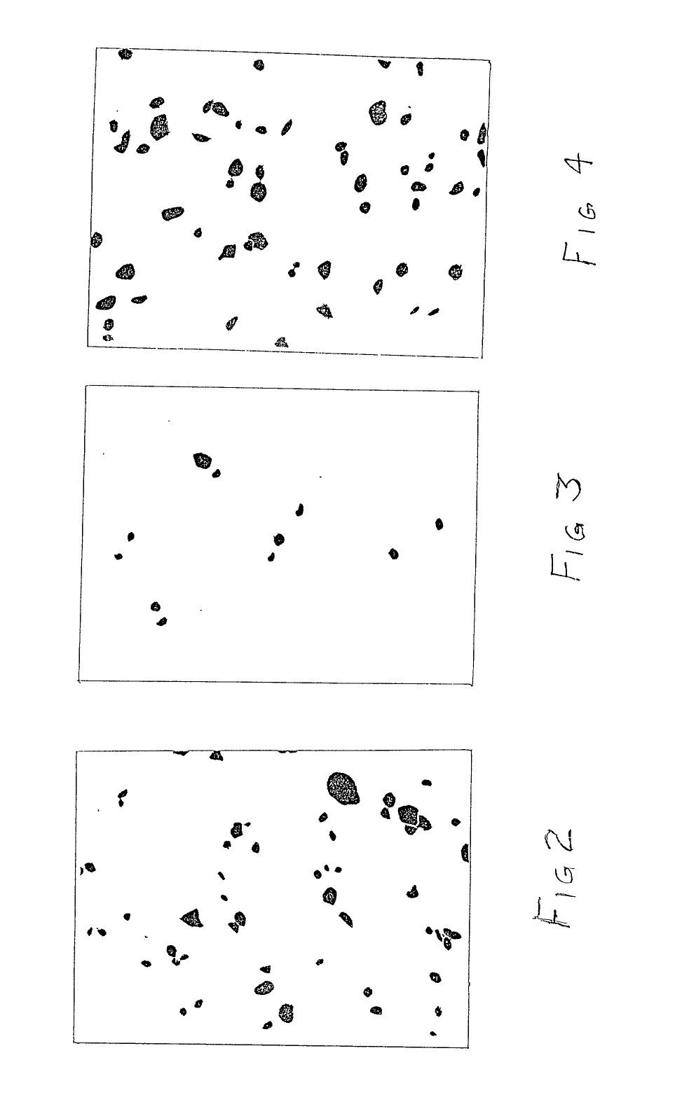

Table 1 is the data relating to the particle loading of the surface for the examples 1 and 2 described above. The particle loading of Example 3 will be comparable with Example 2. The data of Table 1 shows that the step of etching a conventional brush grained plate of the prior art removes a very significant percentage of the calcined alpha alumina particles initially embedded by the brush graining. This is illustrated by the particle count, the count of the vacant imprints which have been left in the plate surface by the removed particles and the percentage of the surface covered by particles and vacant imprints. The particle loading of the plates of Examples 1 and 2 are shown in FIGS. 2 and 3. FIG. 2 shows the particles in a section of plate at 1500× magnification for Example 1 which represent the present invention. FIG. 3 shows the particles in a section of plate for Example 2 which represents the prior art. The significant differences in the particle counts and area covered by particles can be clearly seen. FIG. 4 shows the vacant imprints which have been left in the plate by particles removed by post treatment.

TABLE 1

| | | | | Area covered |
|---|---|---|---|---|
| | | Vacant | Area covered by | by vacant |
| | | particle | particles | imprints |
| | Particles/m² | imprints/m² | % | % |
| Example 1 | 1.95 × 10¹⁰ | | 5.13 | |
| Example 2 | 0.52 × 10¹⁰ | 1.91 × 10¹⁰ | 1.04 | 5.33 |

TABLE 2

| Time | | | |
|---|---|---|---|
| msec | Example 1 | Example 2 | Example 3 |
| 20 | 13.9° | 27.3° | 19.0° |
| 40 | 12.0° | 26.9° | 15.0° |
| 60 | 11.5° | 26.8° | 13.0° |
| 80 | 11.0° | 26.8° | 12.7° |
| 100 | 10.3° | 26.7° | 12.0° |
| 120 | 9.8° | 26.7° | 11.3° |
| 140 | 9.1° | 26.7° | 10.9° |

Examples were then tested for hydrophilicity or wettability by measuring the contact angle of a drop of water on the plate surface over a period time using a Kr\ddot{uss}Drop Shape Analyzer Model DSA MK2 available from Kr\ddot{uss}U.S.A. of Charlotte, N.C. A drop size of 2 microliters was used for each measurement. Table 2 is the data relating to the measured contact angles for the Examples 1 to 3 as the water drops spread over the plate for 140 milliseconds. The data of Table 2 quite clearly shows the increased hydrophilicity of the plate of Example 1 according to the present invention as compared to the plate of Example 2 which was etched according to the prior art to remove particles. This is illustrated by the low contact angles for Example 1 as compared to Example 2. This Table 2 also shows that the post treatment of the plate of Example 2 with sodium silicate to form the plate of Example 3 significantly decreases the contact angle and increases this initial hydrophilicity to a point close to the plate of the present invention in Example 1. However, as will be illustrated below, this increased hydrophilicity of the plate of Example 3 is only temporary.

The plates prepared according to Example 1 and Example 3 were then prepared for printing by applying a conventional imageable lithographic printing plate coating and identically imaged. They were then run on a printing press under identical conditions for 140,000 impressions. After the press run, the plates were removed from the press and cleaned with a standard plate cleaner. The contact angle with water of the non-image area of each plate, now identified as Examples 1A and 3A, was then measured with the results set forth in Table 3.

TABLE 3

| Time/seconds | Example 1A | Example 3A |
|---|---|---|
| 1 | 27.0° | 53.1° |
| 2 | 24.5° | 49.6° |
| 3 | 23.0° | 47.7° |
| 4 | 22.7° | 46.5° |
| 5 | 21.7° | 45.7° |

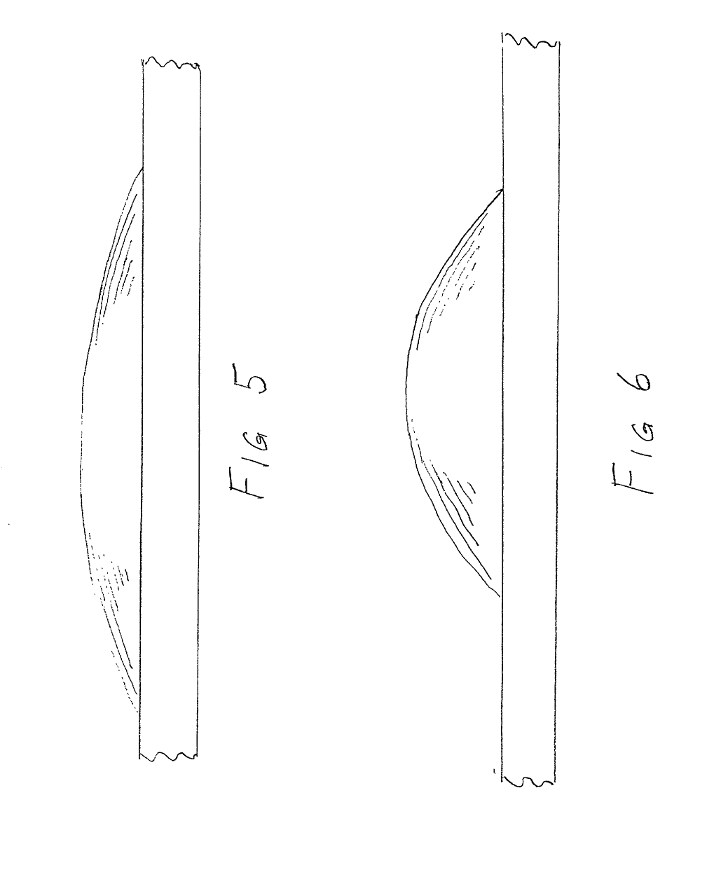

As can be seen, the Example 1A plate has a significantly lower contact angle and thus higher hydrophilicity than the Example 3A plate. The initial increased hydrophilicity of the plate of Example 3, which was achieved by post treatment, was only temporary. This can be visually seen in FIGS. 5 and 6 which are taken from actual magnified images of the droplet shape on the surface of the plates being tested. FIG. 5 is the droplet shape for Example 1A and FIG. 6 is the droplet shape of Example 3A. Although the magnification of these illustrated droplets is not known, the relative diameters of the droplets were compared and the relative surface area coverage was calculated. The droplet of FIG. 5 (Example 1A) has a diameter of 13.4 lineal units and an area of 141 area units whereas the droplet of FIG. 6 (Example 3A) has a diameter of 9.5 lineal units and an area of 71 area units. Therefore, the area of the plate covered by the 2 microliter droplet on the surface of the plate of the present invention is approximately twice that of the prior art. This illustrates that the inventive plate surface will require significantly less fountain solution to wet the surface. The surface of the substrate of the present invention may optionally be post treated if required to prevent the sensitized coating from adversely interacting with the anodized aluminum surface prior to the imaging process. The post treatment does not adversely alter the improvement of the present invention.

The effect of the present invention was tested by running a plate according to Example 1 and a plate according to the prior art such as U.S. Pat. No. 4,731,317 and as in Example 3 on two parallel commercial newspaper printing presses with the plates containing identical images. The plates were run for 104,500 impressions. The test was then repeated switching the plate of the invention and the plate of the prior from the one press to the other to assure that the test results were not affected by the particular press.

The average reduction in consumption of ink was 15% and the average reduction in consumption of fountain solution was 32%.

Although not wishing to be bound by any particular theory or mechanism, the following is believed to be relevant to the present invention. In general, the higher the surface free energy of a solid substrate, the greater the wettability with water. Typically, metal oxides have a high surface free energy. The heat of adsorption for a gas or a liquid is another method of quantifying the strength of the absorption for different solid materials. For calcined aluminum oxide (alpha alumina), the heat of water adsorption is very high. The surface free energy of calcined alumina is also very high because of coordination vacancies on the surface. Al³ and O² sites are present and cause water to be dissociatively absorbed with the release of heat. The water dissociatively adsorbs on the surface of the calcined alumina until a monolayer of aluminum hydroxyls forms. After the formation of a complete monolayer of hydroxyl groups, the next layer of water is absorbed by hydrogen bonding and consists of molecular water. The heat of adsorption for hydrogen bonding is much less than for dissociative absorption.

With its high hydrophilicity, the ideal ink-water balance is easier to attain and the plate cleans up more rapidly, thus reducing the makeready waste at start-up. Also, the plate runs cleaner throughout the press run. And most importantly, the inventive plate retains the improved hydrophilicity during the press run as compared with conventionally grained, anodized and post treated plates. The printing press can therefore be run at lower fountain consumption settings.

1. A lithographic printing plate having increased hydrophilicity comprising
a. a substrate comprising:
i. an aluminum base; and
ii. a quantity of calcined alpha
alumina particles firmly
embedded in and protruding
from a surface of said aluminum
base, said calcined alpha
alumina particles having particle
sizes less than 10 microns and
said quantity being such that at
least 2 percent of the area of
said surface is occupied by said
particles ; and
b. a coating on said substrate said coating being
imageable by radiation of a selected
wavelength and containing a radiation
absorber for said radiation of said selected
wavelength.

2. A lithographic printing plate as recited in claim 1 wherein said coating has a composition which interacts with said radiation of said selected wavelength to image said coating by a process selected from solubilization, insoubilization and internal ablation.

3. A method of producing a lithographic printing plate which is imageable by radiation of a selected wavelength and having increased hydrophilicity comprising the steps of:
a. providing an aluminum base;
b. graining a surface of said aluminum base with
calcined alpha alumina particles having
particle sizes less than 10 microns and
thereby embedding a quantity of said calcined
alpha alumina particles in said surface, said
quantity being such that at least 2 percent of
the area of said surface is occupied by said
particles producing increased hydrophilicity;
and
c. while maintaining said quantity of embedded
calcined alpha alumina particles, applying an
imageable coating to said surface of said
grained alumina base, said imageable coating
containing an absorber for said radiation of
said selected wavelength.

4. A method as recited in claim 3 wherein said coating has a composition which interacts with said radiation of said selected wavelength to image said coating by a process selected from solubilization, insolubilization and internal ablation.

5. A method as recited in claim 3 wherein said graining comprises brush graining.

6. A method as recited in claim 3 and further comprising the step of anodizing said aluminum base between said embedded calcined alpha alumina particles.

7. A process of lithographically printing with reduced ink/water requirements comprising applying a printing image to the lithographic printing plate of claim 1 and lithographically printing with said imaged plate on a printing press using reduced rates of application of ink and water to said plate in accordance with the increased hydrophilicity of said plate.

8. A lithographic printing plate having increased hydrophilicity comprising
a. a substrate comprising:
i. an aluminum base; and
ii. a quantity of high surface free
energy metal oxide particles
firmly embedded in and
protruding from a surface of
said aluminum base, said
particles having particle sizes
less than 10 microns and said
quantity being such that at least
2 percent of the area of said
surface is occupied by said
particles ; and
b. a coating on said substrate said coating being imageable by radiation of a selected wavelength and containing a radiation absorber for said radiation of said selected wavelength.
